(19) United States
(12) Patent Application Publication
(10) Pub. No.: US 2014/0360555 A1
(43) Pub. Date: Dec. 11, 2014

(54) PHOTOVOLTAIC POWER CURTAILMENT METHODS AND SYSTEMS

(71) Applicant: SUNEDISON LLC, BELTSVILLE, MD (US)

(72) Inventors: Peter DooHyon Kim, San Francisco, CA (US); Andras Boross, San Francisco, CA (US)

(21) Appl. No.: 14/300,921

(22) Filed: Jun. 10, 2014

Related U.S. Application Data
(60) Provisional application No. 61/833,241, filed on Jun. 10, 2013.

(51) Int. Cl. G01S 3/786; H01L 31/042

(52) U.S. Cl. CPC G01S 3/7861; H01L 31/0422
USPC 136/246

(57) ABSTRACT

Photovoltaic (PV) power curtailment methods and systems are disclosed. One example is a method of reducing a power output of a PV array including at least one tracking device operated to rotate the PV modules about at least the first axis of rotation to substantially maintain a first angle of incidence of solar radiation on the PV modules. The method includes determining a power output of the PV array, and in response to a determination to reduce the power output of the PV array to a reduced power output, rotating the PV modules away from the first angle of incidence using the at least one tracking device until the power output of the PV array is substantially equal to a reduced power output.

### CROSS REFERENCE TO RELATED APPLICATIONS

This application claims priority to U.S. Provisional Application No. 61/833,241 filed Jun. 10, 2013, the entire disclosure of which is hereby incorporated by reference in its entirety.

### FIELD

The field of the present disclosure relates generally to photovoltaic modules and arrays. More specifically, the present disclosure relates to systems and methods of power curtailment for photovoltaic modules and arrays.

### BACKGROUND

In some known solar power systems, a plurality of photovoltaic (PV) modules (also known as solar modules) are logically or physically grouped together to form an array of PV modules. Each PV module includes a PV laminate (also known as a solar laminate) that converts solar energy into electrical energy. The electrical energy may be used directly, converted for local use, and/or converted and transmitted to an electrical grid or another destination.

PV modules generally output direct current (DC) electrical power. To properly couple such PV modules to an electrical grid, or otherwise provide alternating current (AC) power, the electrical power received from the solar modules is converted from DC to AC power using a DC/AC inverter. Some known systems couple the DC output of more than one PV module to a single inverter. In some systems, an array of PV modules includes a plurality of PV modules arranged in strings of PV modules. Each string of modules is connected to a single inverter to convert the DC output of the string of PV modules to an AC output. In at least some other known systems, each PV module is coupled to its own inverter. Each inverter may be positioned near or on the PV module to which it is electrically coupled.

Typically, PV arrays are fixed above an underlying support structure by a rack. The rack may position one or more PV module of the PV array at an angle relative to the support surface to optimize an angle of incidence between the solar array and the incident sunlight. Optimizing the angle of incidence (i.e., maximizing the perpendicular or normal incidence) increases the amount of solar energy gathered by the solar array. Fixed racks are generally set at a fixed angle. However, at certain times of the day, the angle of incidence of the direct sunlight with respect to the one or more of the PV modules is not normal (e.g., because the position of the sun changes throughout the day), which reduces the power output from the PV modules.

Solar trackers (sometimes referred to herein as trackers or tracking devices) are sometimes used to alter the position of one or more PV modules mounted to the tracker to attempt to maintain the desired angle of incidence of direct sunlight on the PV modules. This substantially maximizes the solar energy that is received by the PV modules throughout the day. The introduction of trackers can boost the output energy of a solar power plant by 10%-35%.

There are periods of time and/or circumstances when the output power of a PV module (or an array of PV modules) needs to be curtailed (i.e., reduced), such as for the benefit of transmission grid stability and/or system reliability/performance. Typically, when the output power of a PV module or modules must be curtailed, the output is reduced by controlling the inverter(s) coupled to the PV modules to provide a reduced power output. Some known PV installations include an inverter that, for economic reasons, is undersized relative to the DC to AC power ratio called for in the system's design. In such systems, the inverter is not sized to convert all of the power produced by the PV module(s) when the PV module(s) are operating at their peak output. Therefore, the inverter curtails the power output of a PV system at the inverter (clipping the power output) when the PV modules are producing at levels higher than the allowed/desired maximum/limit.

When power curtailment is achieved through the inverter, the PV modules are subjected to more solar energy than is necessary to provide the curtailed power output. Solar energy incident on a PV module increases its temperature. Accordingly, in a system in which power curtailment is achieved through inverter control, the PV modules are exposed to more solar energy than is needed to produce the curtailed power output and the temperature of the PV modules is correspondingly higher than it would be without curtailment. The electrical power produced by PV modules decreases proportionally with an increase in module temperature. For example, an increase in the temperature of a crystalline silicon PV module by 20-30° C. may result in a 10-15% reduction in power output for the PV module. In some circumstances, such as PV installations in the Middle East, PV modules temperatures can increase by 65° C., with PV module surface temperatures reaching or exceeding 80° C. in the summer. Moreover, higher PV module temperatures may increase material degradation, such as thermal fatigue failure of interconnections between PV cells in the PV module. Accordingly, PV modules may benefit from reduced temperatures and/or from reducing a rate of increase in temperature.

Additionally, electric utilities attempt to keep the electric grid balanced, with the generated power equal to the consumption. However, power consumption is very dynamic, forcing electric utilities to constantly balance output to changes in power consumption. The utilities utilize many different power sources, like coal fired, gas fired, hydro, thermo, solar and many more. Some of these power sources are throttled as required to maintain grid stability. However, as intermittent sources like solar and wind energy are added to the grid, maintaining grid stability becomes increasingly more challenging. As a result, the utilities are requiring solar PV systems to provide a controlled ramp up/down of power over a period of time to improve the utility's ability to maintain grid stability.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is a photovoltaic (PV) system including a PV array and a controller. The PV array includes a plurality of PV modules and at least one of tracking device. The plurality of PV modules are mounted to the at least one tracking device. The at least one tracking device is configured to rotate the PV module about at least a first axis of rotation. The controller is operatively coupled to the at least one tracking device. The controller is configured to control the at least one tracking device to rotate the PV modules about at least the first axis of rotation to substantially maintain a first angle of incidence of solar radiation on the PV modules, determine a second angle of incidence of solar radiation on the PV modules that will reduce a power output of the PV array by a determined amount, and control the at least one tracking device to rotate the PV modules about at least the first axis of rotation to the second angle of incidence.

Another aspect is a photovoltaic (PV) system including a PV array and a controller. The PV array includes a plurality of PV modules and at least one tracking device, the plurality of PV modules mounted to the at least one tracking device. The tracking device is configured to rotate the PV module about at least a first axis of rotation. The controller is operatively coupled to the at least one tracking device. The controller is configured to control the at least one tracking device to rotate the PV modules about at least the first axis of rotation to substantially maintain a first angle of incidence of solar radiation on the PV modules, determine a power output of the PV array, and in response to a determination to reduce the power output of the PV array to a reduced power output, control the at least one tracking device to rotate the PV modules away from the first angle of incidence until the power output of the PV array is substantially equal to a reduced power output.

In another aspect of the disclosure, a method of reducing a power output of a photovoltaic (PV) array including at least one tracking device operated to rotate the PV modules about at least the first axis of rotation to substantially maintain a first angle of incidence of solar radiation on the PV modules is described. The method includes determining, from a lookup table, a second angle of incidence of solar radiation on the PV modules that will reduce a power output of the PV array by a determined amount, and rotating the PV modules about at least the first axis of rotation to the second angle of incidence using the at least one tracking device.

One aspect of the disclosure is a method of reducing a power output of a photovoltaic (PV) array including at least one tracking device operated to rotate the PV modules about at least the first axis of rotation to substantially maintain a first angle of incidence of solar radiation on the PV modules. The method includes determining a power output of the PV array, and in response to a determination to reduce the power output of the PV array to a reduced power output, rotating the PV modules away from the first angle of incidence using the at least one tracking device until the power output of the PV array is substantially equal to a reduced power output.

According to still another aspect of the disclosure, a method of reducing a power output of at least one photovoltaic (PV) module mounted on a tracking device includes determining a power output of the at least one PV module, and moving, using the tracking device, the at least one PV module away from a first position at which a maximum amount of solar radiation is incident on a face of the at least one PV module until the power output of the at least one PV module is substantially equal to a predetermined reduced power output.

Another aspect is a method of reducing a power output of at least one photovoltaic (PV) module mounted on a tracking device, where the tracking device positions the at least one PV module in a first position at which a maximum amount of solar radiation is incident on a face of the at least one PV module. The method includes determining, from a lookup table, a second position of the at least one PV module that will reduce a power output of the at least one PV module by a determined amount, and moving, using the tracking device, the PV module to the second position.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a perspective view of a photovoltaic (PV) module of an embodiment.

FIG. 2 is a cross-sectional view of the PV module of FIG. 1 taken along the line A-A of FIG. 1.

FIG. 3 is a block diagram of a PV system including a PV module, a tracking device, and a controller.

FIG. 4 is a perspective view of a PV system including a tracking system.

FIG. 5 is a side elevation view of a PV system including a PV module mounted to a tracking device, with the PV module in a first position.

FIG. 6 is a side elevation view of the PV system shown in FIG. 5, with the PV module rotated to a second position.

FIG. 7 is a graph of maximum output power of an exemplary PV system as a function of time of day.

FIG. 8 is another graph of maximum output power of an exemplary PV system as a function of time of day.

Like reference symbols in the various drawings indicate like elements.

### DETAILED DESCRIPTION

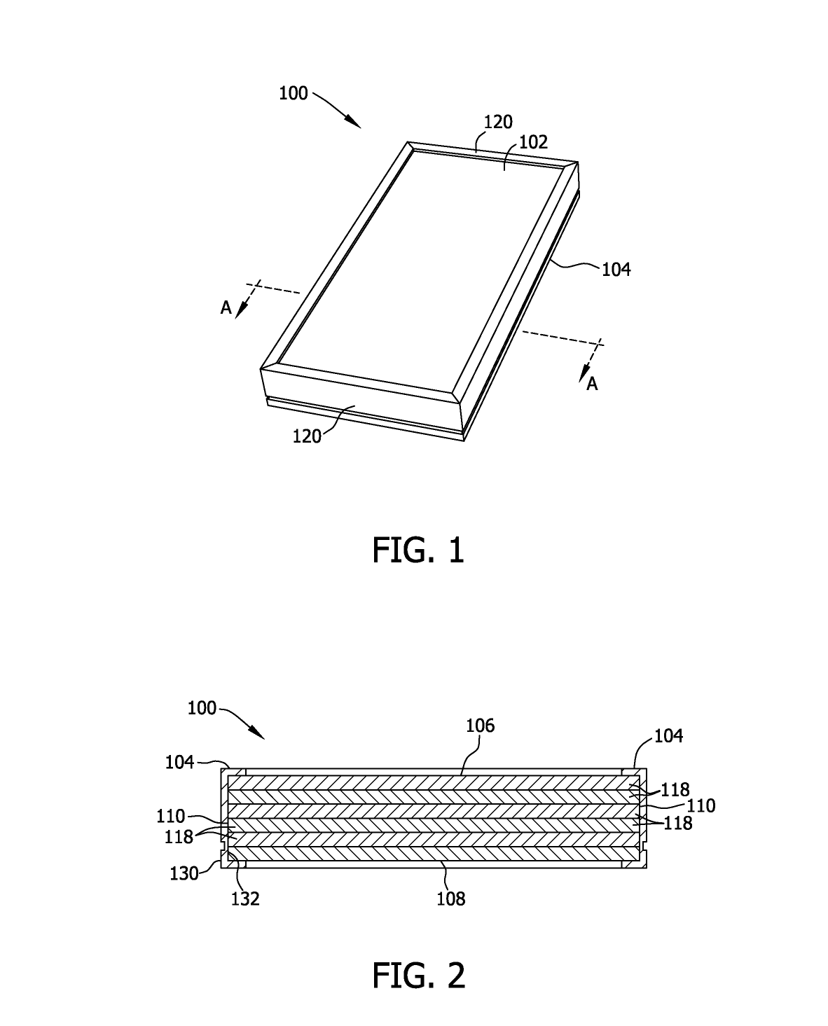

Referring to FIG. 1, an embodiment of a photovoltaic (PV) module is generally designated 100. In this embodiment, PV module 100 includes a solar panel 102. Solar panel 102 includes a top surface 106 and a bottom surface 108 (shown in FIG. 2). Edges 110 extend between top surface 106 and bottom surface 108. In this embodiment, solar panel 102 is rectangular shaped. In other embodiments, solar panel 102 may have any shape that allows the PV module 100 to function as described herein.

Frame 104 circumscribes and supports solar panel 102. Frame 104 is coupled to solar panel 102, for example as shown in FIG. 2. In this embodiment, frame 104 also protects the edges 110 of solar panel 102. Frame 104 includes an outer surface 130 spaced apart from solar panel 102 and an inner surface 132 adjacent to solar panel 102. In this embodiment, outer surface 130 is spaced apart from, and substantially parallel to, inner surface 132. In this embodiment, frame 104 is made of aluminum, such as 6000 series anodized aluminum, but the frame may be made of any suitable material providing sufficient rigidity including, for example, metal or metal alloys, plastic, fiberglass, carbon fiber and the like.

FIG. 2 is a cross-sectional view of PV module 100 taken at line A-A shown in FIG. 1. In this embodiment, solar panel 102 has a laminate structure that includes a plurality of layers 118. Layers 118 include, for example, glass layers, non-reflective layers, electrical connection layers, n-type silicon layers, p-type silicon layers, backing layers and combinations thereof. In other embodiments, solar panel 102 may have more or fewer layers 118 than shown in FIG. 2, including only one layer.

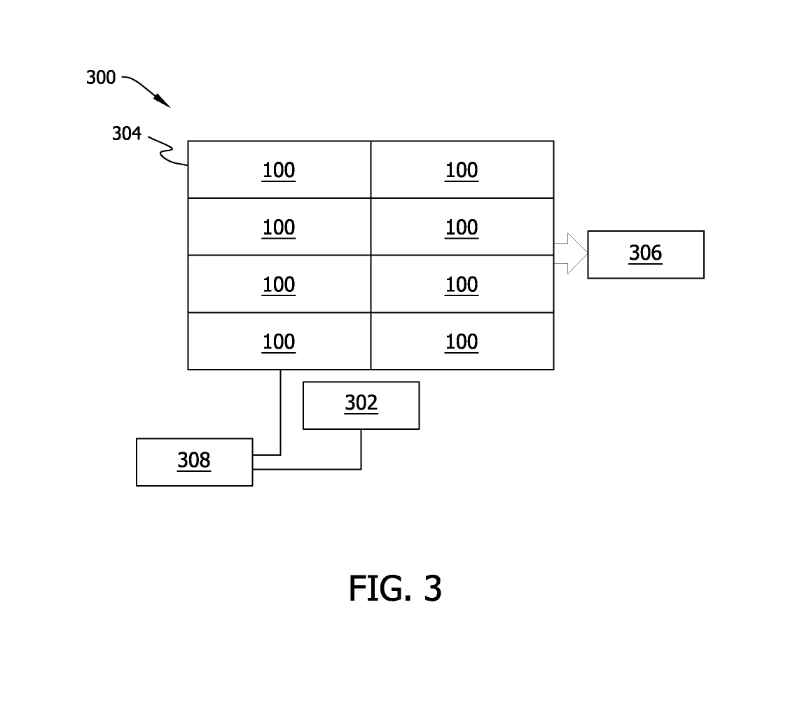

FIG. 3 is a block diagram of an exemplary PV system 300. The PV system 300 includes a plurality of PV modules 100 mounted to a tracking device 302. The plurality of PV modules 100 are arranged in a PV array 304. The PV array 304 may include any suitable number of PV modules 100. Moreover, in some embodiments, a single PV module may be mounted to the tracking device 302. In still other embodiments, more than one array 304 may be mounted to the tracking device 302.

The PV system 300 includes an inverter 306. In the exemplary embodiment, the power output from all of the PV modules 100 of the PV array 304 is provided to inverter 306. The inverter 306 may be located on or close to the PV array 304 to which it is coupled, or may be remotely located. In other embodiments, each PV module 100 includes its own inverter 306. The inverter 306 may be attached to the bottom surface 108 of the solar panel 102, the frame 120 of the PV module 100 adjacent the bottom surface 108 of the solar panel 102, or remotely located from the PV module 100.

The PV array 304 provides its DC power output to the inverter 306. The inverter 306 converts the DC power to an AC power output. The exemplary inverter 306 is a two stage power converter including a first stage and a second stage (not shown). The first stage is a DC/DC power converter that receives a DC power input from the PV array 304 and outputs DC power to the second stage. The DC/DC converter may be any suitable DC/DC converter including, for example, a buck converter, a boost converter, a buck-boost converter, an LLC DC/DC converter, etc. The second stage is a DC/AC power converter that converts DC power received from the first stage to an AC power output. The second stage may be any suitable DC/AC power converter including, for example, an H-bridge. In other embodiments, inverter 306 may include more or fewer stages. More particularly, in some embodiments inverter 306 includes only a single stage. In some embodiments, the inverter 306 implements maximum power point tracking (MPPT) to attempt to operate to extract the maximum power output from the PV array 304.

The PV system 300 includes a controller 308. In the exemplary embodiment, the controller 308 controls operation of the tracking device 302. More specifically, controller 308 controls operation of tracking device 302 to move the PV array 304 to track sunlight to control that amount of solar energy incident on the PV modules 100 and thereby control the amount of power output by the PV system 300. In some embodiments, the controller 308 is also configured to control the inverter 306.

The controller 308 may be any suitable controller for performing as described herein, including any suitable analog controller, digital controller, or combination of analog and digital controllers. In some embodiments, the controller 308 includes a processor (not shown) that executes instructions for software that may be loaded into a memory device. The processor may be a set of one or more processors or may include multiple processor cores, depending on the particular implementation. Further, the processor may be implemented using one or more heterogeneous processor systems in which a main processor is present with secondary processors on a single chip. In another embodiment, the processor may be a homogeneous processor system containing multiple processors of the same type. In some embodiments, the controller 308 includes a memory device (not shown). As used herein, a memory device is any tangible piece of hardware that is capable of storing information either on a temporary basis and/or a permanent basis. The memory device may be, for example, without limitation, a random access memory and/or any other suitable volatile or non-volatile storage device. The memory device may take various forms depending on the particular implementation, and may contain one or more components or devices. For example, the memory device may be a hard drive, a flash memory, a rewritable optical disk, a rewritable magnetic tape, and/or some combination of the above. The media used by memory device also may be removable. For example, without limitation, a removable hard drive may be used for the memory device.

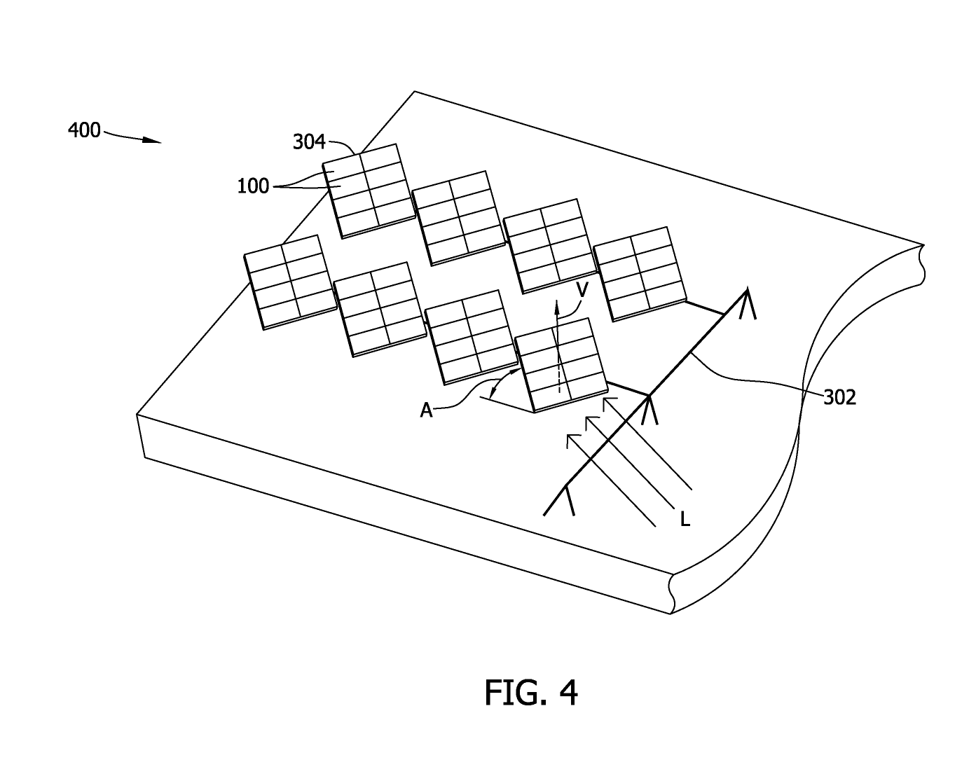

Generally, The controller 308 controls operation of the tracking device 302 to position PV array 304 to attempt to maximize normal incidence of sunlight incident on PV array 304. If the incident sunlight shifts such that the angle of incident light with respect to PV arrays 304 changes, for example as the sun moves across the sky, controller 308 controls operation of the tracking device 302 to control the position of PV array 304 to maximize normal incidence of incident light rays L. Tracking device 302 positions the PV arrays 304 at an angle A (shown in FIG. 4) with respect to a horizontal plane. Angle A is set to maximize normal incidence of light rays L with respect to PV array 304. In some embodiments, tracking device 302 is a single axis tracking device (e.g., a horizontal axis tracking device, not shown), that permits controlled adjustment of the angle A between about −45 degrees to 45 degrees, depending upon the angle of the incident light. In other embodiments, angle A is a fixed angle, and tracking device 302 is configured for controllable rotation of arrays 304 around a vertical axis V (shown in FIG. 4). Moreover, in some embodiments, tracking device 302 is a multi-axis tracking device that is configured to permit variation of the position of PV arrays 304 around at least two axes (e.g. to vary angle A and rotate around axis V). In some embodiments, tracking device 302 is operable to alter the position of one or more of PV module independent of the movement of the other PV modules.

The controller 308 is configured to receive instructions regarding power output of the PV system 300. The received instructions may indicate a desired power output of the PV system, a desired change (reduction or increase) in output power (whether given as a percentage or in units of power, such as watts, horsepower, calories, etc.), a desired rate of change of output power, etc. The instructions may be received from, for example, a utility company, another controller 308, a central controller for system including a plurality of PV systems 300, or any other suitable source for such an instruction. In some embodiments, the controller 308 determines a reduced power output (i.e., a target power output) based on the received instruction. In some instances, the value of the reduced power output is provided in the instructions, while in other instances the controller 308 must calculate the value of the reduced power output based on the instructions (such as when the instructions indicate a percentage reduction or an amount of reduction).

The controller 308 is configured to control the tracking device 302 to change the angle of incidence of solar radiation on the face of the PV modules 100 to comply with the received instructions. For example, when the received instruction requests a reduction in output power, the controller 308 is configured to control the tracking device 302 to change the angle of incidence of sunlight on the PV modules 100 to reduce the maximum power produced by the PV system 300 as requested. The inverter 306 continues to operate to produce the maximum power output from the PV system 300, but the maximum possible power output of the PV system 300 is reduced by the changed position of the PV array 304.

In a preferred embodiment, the maximum power output of the PV system 300 is reduced using a closed loop feedback system. The controller 308 monitors (such as via one or more sensors, or by reading or receiving a signal from an AC meter, a production meter, and/or an inverter output) the power output of the PV system 300. The controller may read and/or receive signals from an AC meter, a production meter, and/or an inverter output via established communication channels such as ModBus, DNP3, RS-485, TCP/IP. In response to an instruction to reduce the power output of the PV system 300, the controller 308 controls the tracking device 302 to rotate the PV array 304 away from its current position (sometimes referred to as a first position) until the monitored power output of the system 300 is substantially equal to the determined reduced power output. The controller 308 continues to control the tracking device to attempt to maintain power output at the reduced power output. The controller 308 may maintain the reduced power output until a further instruction is received, until a predetermined time has elapsed, for a length of time contained in the received instruction, until a particular time of day, etc.

In another embodiment, the maximum power output of the PV system 300 is reduced using a look-up table stored in the memory of the controller 308. In this embodiment, controller determines a position of the PV array 304 that will produce the desired reduced power output by looking it up in a lookup table. The lookup table may list the amount of change to the position of the PV array 304 to achieve a particular percentage change in output power, may list a particular position of the PV array 304 to achieve a particular power output (which may vary based on other inputs, such as time of day, season of the year, etc.), or may list the necessary information to adjust the output power in any other suitable format.

In still other embodiments, the maximum power output of the PV system 300 is reduced by altering the position of the PV array 304 based on one or more equations stored in the memory of the controller 308.

FIG. 4 is a perspective view of an exemplary embodiment of a PV system 400. Except as otherwise described herein, PV system 400 is substantially the same as PV system 300. PV system 400 includes a plurality of PV modules 100 mounted to a tracking device 302. In this embodiment, the plurality of PV modules 100 arranged in more than one PV arrays 304. The PV arrays 304 are all moved and maintained in similar positions by the tracking device 302. Alternatively, one or more PV array 304 may be moved by tracking device 302 independently of the movement (or lack thereof) of the other PV arrays 304.

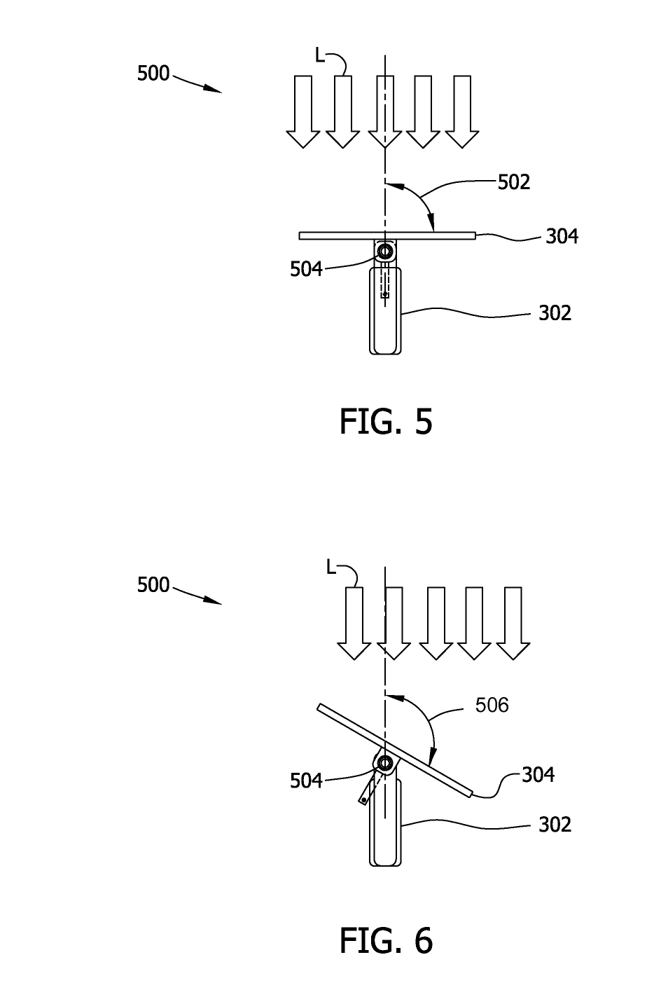

FIGS. 5 and 6 are side elevation views of an exemplary PV system 500. Except as otherwise described herein, PV system 500 is substantially the same as PV system 300. In the illustrated embodiment, tracking device 302 is a horizontal single axis tracker configured to rotate the PV array about an axis of rotation (going into the page) at point 504. In FIG. 5, the PV array 304 is in a first position with the sunlight L incident on the PV modules 100 at a first angle of incidence 502. In the illustrated orientation, the first angle of incidence 502 is about ninety degrees and the PV modules 100 are receiving the maximum solar energy. To reduce the power output of the PV array 304, the controller 308 (shown in FIG. 3) causes the tracking device 302 to rotate the PV array 304 around the axis of rotation to a second angle of incidence 506. FIG. 6 shows the PV system 500 after the rotation to the second angle of incidence 506. At the second angle of incidence 504, less solar energy is received by the PV modules 100 and the maximum power output of the PV modules 100 (and the array 304) is correspondingly decreased.

In exemplary embodiments, the controller 308 rotates the PV array 304 in the west direction to decrease the power output of the PV array. Alternatively, the PV array 304 may be rotated in any other direction. In the exemplary embodiment, rotation to the west is used because the sun is moving to the west and tracking device 302 normally rotates PV array 304 from east to west to track the movement of the sun. To reduce the power output, the tracking device 302 is advanced ahead of the sun to the west. To increase a reduced power level after the PV array 304 has been rotated to the west, the controller 308 may maintain the tracking device 302 in position and allow the sun's position to catch up to the tracking device 302 or the controller 308 may actively rotate the tracking device eastward. This provides effective control of output power while maintaining a relatively simple control algorithm.

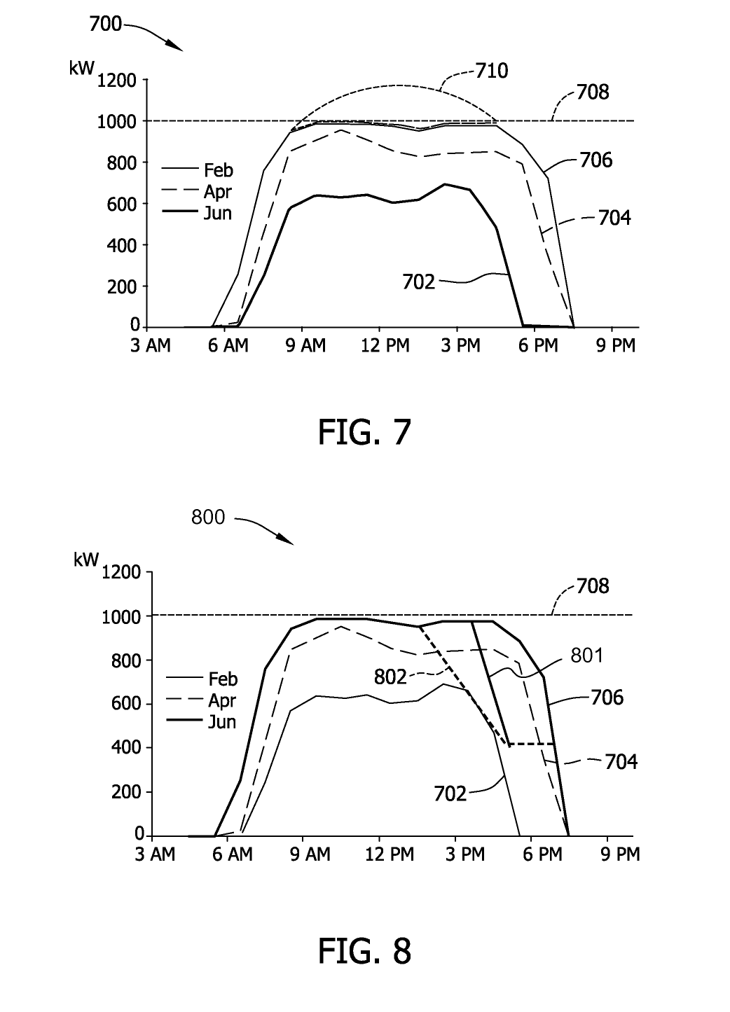

FIGS. 7 and 8 are graphs 700 and 800 (respectively) of maximum output power for a PV system, such as PV system 300, as a function of time of day. In this example, the PV system 300 is a one megawatt PV system with inverter(s) 308 operable to output one megawatt of AC power. The amount of solar energy received by the PV modules 100, and accordingly the maximum power output of the system 300, varies based on the time of the year as well as the time of day. Three curves are plotted on the graphs 700 and 800 presenting the maximum power output of the system 300 during three different months. The first curve 702 presents the power output during the month of February, the second curve 704 presents the power output during the month of April, and the third curve 706 presents the power output during the month of June. Line 708 is a one megawatt reference to which an undersized inverter will clip output power. The dashed curve 710 represents the power that the PV array 304 can produce, but which is clipped by the inverter.

With reference first to FIG. 7, the maximum power output of the system 300 is greater in June than in February and April. Moreover, because the peak in solar energy received (and, hence, peak output power) occurs for a small fraction of the year (typically the summer months), the inverter 308 is undersized and not rated to output the maximum power that the PV array 304 is capable of producing during the peak months in order to reduce the cost of the system 300. Accordingly, when the PV array 304 receives sufficient solar energy to produce an output power greater than one megawatt, the controller 308 changes the position of the PV array 304 as described above to maintain the output power of the PV system 300 at or below one megawatt without clipping by the inverter. This permits the system 300 to operate at a cooler temperature, more efficiently, and generate more power below the clip line 708 (due to the lower module temperature).

FIG. 8 also includes a trace 801 that represents a predicted deviation of output power of the system 300 during the month of June (i.e., curve 706) when clouds drastically reduce the sunlight incident on the PV array 304 in the late afternoon. Rapid changes to system output may adversely impact grid stability. Accordingly, some grid operators are requesting and/or requiring PV systems to provide controlled ramp up and/or ramp down of system output power. In FIG. 8, trace 802 is the desired ramp down profile requested by a grid operator. By controlling the angle of incidence of the array 304 to the sunlight as described above, the power output of the system 300 can be controlled to reduce the power output at the requested rate represented by trace 802. Specifically, the controller 308 begins to gradually decrease the power output of the system 300 before the clouds force the output power down. As the clouds reduce the sunlight incident on the PV modules, the controller 308 can reposition the PV array 304 to change the angle of incidence (whether to increase or decrease the amount of solar radiation incident on the PV modules 100) to maintain the desired ramp rate.

The systems and methods described herein may facilitate improved control of the power output of a PV array by moving the PV array to adjust the amount of solar energy receive by the array. This adjustment allows an inverter coupled to the PV array to operate to extract the maximum power it can from the array, while avoiding unnecessary temperature increases (and corresponding decrease in efficiency) in the PV modules that make up the array. Moreover, controlled increases and decreases in output power may be achieved, thereby aiding grid stability.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above apparatus and methods without departing from the scope of the disclosure, it is intended that all matter contained in the above description and shown in the accompanying figures shall be interpreted as illustrative and not in a limiting sense.

In some embodiments, the above described systems and methods are electronically or computer controlled. The embodiments described herein are not limited to any particular system controller or processor for performing the processing tasks described herein. The term controller or processor, as used herein, is intended to denote any machine capable of performing the calculations, or computations, necessary to perform the tasks described herein. The terms controller and processor also are intended to denote any machine capable of accepting a structured input and of processing the input in accordance with prescribed rules to produce an output. It should also be noted that the phrase “configured to” as used herein means that the controller/processor is equipped with a combination of hardware and software for performing the tasks of embodiments of the invention, as will be understood by those skilled in the art. The term controller/processor, as used herein, refers to central processing units, microprocessors, microcontrollers, reduced instruction set circuits (RISC), application specific integrated circuits (ASIC), logic circuits, and any other circuit or processor capable of executing the functions described herein.

The computer implemented embodiments described herein embrace one or more computer readable media, including non-transitory computer readable storage media, wherein each medium may be configured to include or includes thereon data or computer executable instructions for manipulating data. The computer executable instructions include data structures, objects, programs, routines, or other program modules that may be accessed by a processing system, such as one associated with a general-purpose computer capable of performing various different functions or one associated with a special-purpose computer capable of performing a limited number of functions. Aspects of the disclosure transform a general-purpose computer into a special-purpose computing device when configured to execute the instructions described herein. Computer executable instructions cause the processing system to perform a particular function or group of functions and are examples of program code means for implementing steps for methods disclosed herein. Furthermore, a particular sequence of the executable instructions provides an example of corresponding acts that may be used to implement such steps. Examples of computer readable media include random-access memory (“RAM”), read-only memory (“ROM”), programmable read-only memory (“PROM”), erasable programmable read-only memory (“EPROM”), electrically erasable programmable read-only memory (“EEPROM”), compact disk read-only memory (“CD-ROM”), or any other device or component that is capable of providing data or executable instructions that may be accessed by a processing system.

A computer or computing device such as described herein has one or more processors or processing units, system memory, and some form of computer readable media. By way of example and not limitation, computer readable media comprise computer storage media and communication media. Computer storage media include volatile and nonvolatile, removable and non-removable media implemented in any method or technology for storage of information such as computer readable instructions, data structures, program modules or other data. Communication media typically embody computer readable instructions, data structures, program modules, or other data in a modulated data signal such as a carrier wave or other transport mechanism and include any information delivery media. Combinations of any of the above are also included within the scope of computer readable media.

1. A photovoltaic (PV) system comprising:
a PV array comprising a plurality of PV modules and at least one of tracking device, the plurality of PV modules mounted to the at least one tracking device, the at least one tracking device configured to rotate the PV module about at least a first axis of rotation; and
a controller operatively coupled to the at least one tracking device, the controller configured to:
control the at least one tracking device to rotate the PV modules about at least the first axis of rotation to substantially maintain a first angle of incidence of solar radiation on the PV modules;
determine a second angle of incidence of solar radiation on the PV modules that will reduce a power output of the PV array by a determined amount; and
control the at least one tracking device to rotate the PV modules about at least the first axis of rotation to the second angle of incidence.

2. The PV system of claim 1, wherein the controller comprises a memory device and the controller is configured to determine the second angle of incidence using a look-up table stored in the memory device.

3. The PV system of claim 2, wherein the controller is configured to determine the second angle of incidence and control the at least one tracking device to rotate the PV modules to the second angle of incidence in response to an instruction to reduce the power output of the PV array.

4. The PV system of claim 3, wherein the instruction to reduce the power output includes the determined amount.

5. The PV system of claim 3, wherein the controller is configured to determine the determined amount based at least in part on the instruction to reduce the power output of the PV array.

6. The PV system of claim 2, wherein the determined amount is a percentage of output power.

7. The PV system of claim 2, wherein the determined amount is an amount of power in units of power.

8. The PV system of claim 1, wherein the controller is configured to control the at least one tracking device to rotate the PV modules to return to and substantially maintain the first angle of incidence of solar radiation on the PV modules in response to an instruction to cease reducing the power output.

9. The PV system of claim 1, further comprising of a plurality of inverters operatively connected to the PV array.

10. A photovoltaic (PV) system comprising:
a PV array comprising a plurality of PV modules and at least one tracking device, the plurality of PV modules mounted to the at least one tracking device, the at least one tracking device configured to rotate the PV module about at least a first axis of rotation; and
a controller operatively coupled to the at least one tracking device, the controller configured to:
control the at least one tracking device to rotate the PV modules about at least the first axis of rotation to substantially maintain a first angle of incidence of solar radiation on the PV modules;
determine a power output of the PV array; and
in response to a determination to reduce the power output of the PV array to a reduced power output, control the at least one tracking device to rotate the PV modules away from the first angle of incidence until the power output of the PV array is substantially equal to a reduced power output.

11. The PV system of claim 10, wherein the controller is configured to determine to reduce the power output of the PV array to the reduced power output in response to a received instruction to reduce the power output of the PV array.

12. The PV system of claim 11, wherein the instruction to reduce the power output indicates the reduced power output.

13. The PV system of claim 11, wherein the controller is configured to determine the reduced power output based at least in part on the instruction to reduce the power output.

14. The PV system of claim 13, wherein the instruction to reduce the power output of the PV array indicates a percentage reduction in the power output.

15. The PV system of claim 13, wherein the instruction to reduce the power output of the PV array indicates an amount of power in units of power by which the power output of the PV array is to be reduced.

16. The PV system of claim 13, further comprising at least one sensor configured to detect at least one component of the power output of the PV array, and wherein the controller is configured to determine the power output of the PV array based at least in part on an output of the at least one sensor.

17. The PV system of claim 13, further comprising an inverter coupled to the PV array, and wherein the controller is configured to receive a signal indicating an output value of the inverter and determine the power output of the PV array based at least in part on the signal indicating the output value of the inverter.

18. The PV system of claim 13, further comprising an AC meter, and wherein the controller is configured to receive a signal indicating an output value of the AC meter and determine the power output of the PV array based at least in part on the signal indicating the output value of the AC meter.

19. The PV system of claim 10, wherein the controller is configured to control the at least one tracking device to rotate the PV modules to return to and substantially maintain the first angle of incidence of solar radiation on the PV modules in response to an instruction to cease reducing the power output.

20. A method of reducing a power output of a photovoltaic (PV) array including at least one tracking device operated to rotate the PV modules about at least the first axis of rotation to substantially maintain a first angle of incidence of solar radiation on the PV modules, the method comprising:
determining, from a lookup table, a second angle of incidence of solar radiation on the PV modules that will reduce a power output of the PV array by a determined amount; and
rotating the PV modules about at least the first axis of rotation to the second angle of incidence using the at least one tracking device.

21. The method of claim 20, further comprising rotating the PV modules to return to and substantially maintain the first angle of incidence of solar radiation on the PV modules in response to an instruction to cease reducing the power output.

22. The method of claim 20, further comprising controlling a plurality of inverters operatively connected to the PV array to reduce the power output at a commanded ramp down rate.

23. The method of claim 20, wherein the second angle of incidence is determined in response to a received instruction to reduce the power output of the PV array.

24-35. (canceled)
